(19) United States
(12) Patent Application Publication
(10) Pub. No.: US 2021/0343831 A1
(43) Pub. Date: Nov. 4, 2021

(54) SEMICONDUCTOR STRUCTURE AND METHOD FOR FORMING SAME

(71) Applicants: Semiconductor Manufacturing International (Shanghai) Corporation, Shanghai (CN); Semiconductor Manufacturing International (Beijing) Corporation, Beijing (CN)

(72) Inventor: Lian Feng HU, SHANGHAI (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 17/101,209

(22) Filed: Nov. 23, 2020

(30) Foreign Application Priority Data
Apr. 30, 2020 (CN) 202010363181.X

(51) Int. Cl. H01L 49/02; H01L 21/02; H01L 21/768

(52) U.S. Cl. CPC H01L 28/75; H01L 21/76834; H01L 21/0228; H01L 21/02274

(57) ABSTRACT

A semiconductor structure and a method for forming same are provided. In some implementations, a forming method includes: providing a base; forming a first electrode layer on the base; and forming a capacitor dielectric layer with a stacked structure on the first electrode layer and a second electrode layer on the capacitor dielectric layer, the capacitor dielectric layer including a bottom high-k dielectric layer, a leakage-proof dielectric layer, and a top high-k dielectric layer that are sequentially stacked from bottom to top, wherein the bottom high-k dielectric layer and the top high-k dielectric layer have a preset total deposition thickness, and wherein a proportion of a deposition thickness of the bottom high-k dielectric layer to the preset total deposition thickness is greater than a proportion of a deposition thickness of the top high-k dielectric layer to the preset total deposition thickness. In implementations of the present disclosure, the respective proportions of the bottom high-k dielectric layer and the top high-k dielectric layer to the preset total deposition thickness are adjusted, so that effective thicknesses of the bottom high-k dielectric layer and the top high-k dielectric layer are both relatively small, thereby alleviating the crystallization problem of the bottom high-k dielectric layer and the top high-k dielectric layer, and further improving reliability of a capacitor structure.

### RELATED APPLICATIONS

The present application claims priority to Chinese Patent Appln. No. 202010363181.X, filed Apr. 30, 2020, the entire disclosure of which is hereby incorporated by reference.

### BACKGROUND

### Technical Field

Embodiments and implementations of the present disclosure relate to the field of semiconductor manufacturing, and in particular, to a semiconductor structure and a method for forming same.

### Related Art

A capacitive element often serves as an electronic passive device in an integrated circuit (such as a radio frequency circuit, a mixed signal circuit, or the like). Common capacitive elements include a metal-oxide-semiconductor (MOS) capacitor, a PN junction capacitor, a polysilicon-insulator-polysilicon (PIP) capacitor, a metal-insulator-metal (MIM) capacitor, and the like.

The MIM capacitor is generally formed on a metal interconnect structure in the back-end of line (BEOL), so that a distance between the MIM capacitor and a silicon substrate is increased, thereby reducing a parasitic capacitor between the MIM capacitor and the substrate, and the performance of the MIM capacitor is not greatly affected by frequency and temperature. In addition, the MIM capacitor is formed in a metal interconnect process, and a forming process of the MIM is compatible with a process of an existing integrated circuit. Therefore, the MIM capacitor has gradually become a mainstream capacitor type of the passive device.

### SUMMARY

A solution provided in the embodiments and implementations of the present disclosure is to provide a semiconductor structure and a method for forming same, so as to improve reliability of an MIM capacitor.

In order to address the foregoing problem, one form of the present disclosure provides a method for forming a semiconductor structure, including: providing a base; forming a first electrode layer on the base; and forming a capacitor dielectric layer with a stacked structure on the first electrode layer and a second electrode layer on the capacitor dielectric layer, the capacitor dielectric layer including a bottom high-k dielectric layer, a leakage-proof dielectric layer, and a top high-k dielectric layer that are sequentially stacked from a bottom to a top, where the bottom high-k dielectric layer and the top high-k dielectric layer have a preset total deposition thickness, and a proportion of a deposition thickness of the bottom high-k dielectric layer to the preset total deposition thickness is greater than a proportion of a deposition thickness of the top high-k dielectric layer to the preset total deposition thickness.

In some implementations, after the first electrode layer is formed on the base, and before the capacitor dielectric layer with a stacked structure is formed on the first electrode layer and the second electrode layer on the capacitor dielectric layer is formed, the forming method further includes: forming a capacitor dielectric film covering the stacked structure of the first electrode layer, the capacitor dielectric film including a bottom high-k dielectric film, a leakage-proof dielectric film, and a top high-k dielectric film that are sequentially stacked from bottom to top, the bottom high-k dielectric film and the top high-k dielectric film having a preset total deposition thickness, and a proportion of a deposition thickness of the bottom high-k dielectric film to the preset total deposition thickness being greater than a proportion of a deposition thickness of the top high-k dielectric film to the preset total deposition thickness; and the step of forming the second electrode layer includes: forming an electrode film covering the capacitor dielectric film; and patterning the electrode film to form a second electrode layer above a part of the first electrode layer; and the step of forming the capacitor dielectric layer includes: after the second electrode layer is formed, removing the capacitor dielectric film exposed from the second electrode layer, and retaining, as the capacitor dielectric layer, the capacitor dielectric film remaining between the second electrode layer and the first electrode layer.

In some implementations, a process for forming the capacitor dielectric film includes an atomic layer deposition process or a plasma chemical vapor deposition process.

In some implementations, the step of removing the capacitor dielectric film exposed from the second electrode layer includes: etching the capacitor dielectric film exposed from the second electrode layer using an anisotropic dry etching process.

In some implementations, in the step of forming a capacitor dielectric layer with a stacked structure on the first electrode layer, a proportion of the deposition thickness of the top high-k dielectric layer to the deposition thickness of the bottom high-k dielectric layer is 0.5 to 0.9.

In some implementations, in the step of forming a capacitor dielectric layer with a stacked structure on the first electrode layer, the deposition thickness of the bottom high-k dielectric layer is 1.5 nanometers to 4 nanometers.

In some implementations, a front layer metal interconnect structure is formed in the base, and a top surface of the front layer metal interconnect structure is exposed from the base; and before the first electrode layer is formed, the forming method further includes: forming an etch stop layer on the base, the etch stop layer covering the front layer metal interconnect structure; forming an interlayer dielectric layer on the etch stop layer; in the step of forming the first electrode layer, the first electrode layer being formed on the interlayer dielectric layer.

In some implementations, the bottom high-k dielectric layer is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate; and the top high-k dielectric layer is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate.

In some implementations, the leakage-proof dielectric layer is made of a material including aluminum oxide, silicon oxide, or silicon nitride.

In some implementations, the first electrode layer is made of nitrided metal.

In some implementations, the first electrode layer is made of a material including TiN, TaN, or WN.

Another form of the present disclosure further provides a semiconductor structure, including: a base; a first electrode layer located on the base; a capacitor dielectric layer with a stacked structure located on the first electrode layer, the capacitor dielectric layer including a bottom high-k dielectric layer, a leakage-proof dielectric layer, and a top high-k dielectric layer that are sequentially stacked from a bottom to a top, the bottom high-k dielectric layer and the top high-k dielectric layer having a preset total deposition thickness, and a proportion of a deposition thickness of the bottom high-k dielectric layer to the preset total deposition thickness being greater than a proportion of a deposition thickness of the top high-k dielectric layer to the preset total deposition thickness; and a second electrode layer located on the capacitor dielectric layer.

In some implementations, a proportion of the deposition thickness of the top high-k dielectric layer to the deposition thickness of the bottom high-k dielectric layer is 0.5 to 0.9.

In some implementations, the deposition thickness of the bottom high-k dielectric layer is 1.5 nanometers to 4 nanometers.

In some implementations, a front layer metal interconnect structure is formed in the base, and a top surface of the front layer metal interconnect structure is exposed from the base; and the semiconductor structure further includes: an etch stop layer located on the base, the etch stop layer covering the front layer metal interconnect structure; and an interlayer dielectric layer located on the etch stop layer, the first electrode layer being located on the interlayer dielectric layer.

In some implementations, the bottom high-k dielectric layer is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate; and the top high-k dielectric layer is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate.

In some implementations, the leakage-proof dielectric layer is made of a material including aluminum oxide, silicon oxide, or silicon nitride.

In some implementations, the first electrode layer is made of nitrided metal.

In some implementations, the first electrode layer is made of a material including TiN, Ti, TaN, Ta, WN, W, or TiW.

In comparison to the prior art, technical solutions of embodiments and implementations of the present disclosure have the following advantages.

In implementations of the forming method, the capacitor dielectric layer with the stacked structure is formed on the first electrode layer, the capacitor dielectric layer including a bottom high-k dielectric layer, a leakage-proof dielectric layer, and a top high-k dielectric layer that are sequentially stacked from a bottom to a top, the bottom high-k dielectric layer and the top high-k dielectric layer having a preset total deposition thickness, and a proportion of a deposition thickness of the bottom high-k dielectric layer to the preset total deposition thickness is greater than a proportion of a deposition thickness of the top high-k dielectric layer to the preset total deposition thickness. At an interface of the first electrode layer and the bottom high-k dielectric layer, the bottom high-k dielectric layer easily reacts with the first electrode layer, thereby consuming a part of the bottom high-k dielectric layer in thickness, so that an effective thickness (that is, a thickness of a high-k dielectric material) of the bottom high-k dielectric layer is reduced. Therefore, the proportion of the deposition thickness of the bottom high-k dielectric layer to the preset total deposition thickness is greater than the proportion of the deposition thickness of the top high-k dielectric layer to the preset total deposition thickness, and when the preset total deposition thickness is unchanged, the deposition thickness of the bottom high-k dielectric layer is increased, and the deposition thickness of the top high-k dielectric layer is decreased, so that the effective thicknesses of the bottom high-k dielectric layer and the top high-k dielectric layer are both small, thereby alleviating the crystallization problem of the bottom high-k dielectric layer and the top high-k dielectric layer, and correspondingly alleviating the leakage current problem caused by crystallization. Accordingly, a breakdown voltage (VBD) of the capacitor dielectric layer is increased, and reliability of the capacitor structure is improved, for example, the performance of time dependent dielectric breakdown (TDDB).

### BRIEF DESCRIPTION OF THE DRAWINGS

FIG. 1 is a schematic structural diagram of a semiconductor structure.

FIG. 2 to FIG. 9 are schematic structural diagrams corresponding to steps in one form of a method for forming a semiconductor structure according to the present disclosure.

### DETAILED DESCRIPTION

Although an MIM capacitor has gradually become the mainstream capacitor type for a passive device, the reliability of the MIM capacitor is currently poor, and application requirements are not easily satisfied. Reasons why the reliability of the MIM capacitor is to be improved are now analyzed in combination with a semiconductor structure.

FIG. 1 is a schematic structural diagram of a semiconductor structure.

The semiconductor structure includes: a base 10; a first electrode layer 40 located on the base 10; a capacitor dielectric layer 50 with a stacked structure located on the first electrode layer 40, the capacitor dielectric layer 50 including a bottom high-k dielectric layer 51, a leakage-proof dielectric layer 52, and a top high-k dielectric layer 53 that are sequentially stacked from bottom to top; and a second electrode layer 60 located on the capacitor dielectric layer 50.

According to a preset capacitance value of the capacitor structure, the total deposition thickness of the bottom high-k dielectric layer 51 and the top high-k dielectric layer 53 may be determined. The bottom high-k dielectric layer 51 has a same deposition thickness as the top high-k dielectric layer 53.

The bottom high-k dielectric layer 51 is used as an example. The bottom high-k dielectric layer 51 is made of a high-k dielectric material, and a larger deposition thickness of the bottom high-k dielectric layer 51 leads to a greater possibility that the bottom high-k dielectric layer 51 is to crystallize, which is likely to cause the problem of leakage current, further causing a drop in the breakdown voltage of the capacitor dielectric layer. Similarly, a larger deposition thickness of the top high-k dielectric layer 53 leads to a greater possibility that the top high-k dielectric layer 53 is to crystallize.

Therefore, the reliability of the capacitor structure currently formed is difficult to be guaranteed.

To address the technical problem, in some forms of the present disclosure, a capacitor dielectric layer with a stacked structure is formed on the first electrode layer. The capacitor dielectric layer includes a bottom high-k dielectric layer, a leakage-proof dielectric layer, and a top high-k dielectric layer that are sequentially stacked from a bottom to a top. The bottom high-k dielectric layer and the top high-k dielectric layer have a preset total deposition thickness, and the proportion of the bottom high-k dielectric layer to the preset total deposition thickness is greater than the proportion of the deposition thickness of the top high-k dielectric layer to the preset total deposition thickness. Since the bottom high-k dielectric layer easily reacts with the first electrode layer at an interface of the first electrode layer and the bottom high-k dielectric layer, thereby consuming a part of the bottom high-k dielectric layer in thickness, so that an effective thickness (that is, a thickness of a high-k dielectric material) of the bottom high-k dielectric layer is reduced. Therefore, the proportion of the deposition thickness of the bottom high-k dielectric layer to the preset total deposition thickness is greater than the proportion of the deposition thickness of the top high-k dielectric layer to the preset total deposition thickness, and when the preset total deposition thickness is unchanged, the deposition thickness of the bottom high-k dielectric layer is increased, and the deposition thickness of the top high-k dielectric layer is decreased, so that the effective thicknesses of the bottom high-k dielectric layer and the top high-k dielectric layer are both small, thereby increasing the breakdown voltage of the capacitor dielectric layer is increased, and further improving the reliability of the capacitor structure, for example, the performance of TDDB.

In order to make the foregoing objectives, features, and advantages of the embodiments and implementations of the present disclosure more apparent and easier to understand, the specific embodiments and implementations of the present disclosure are described in detail below with reference to the drawings.

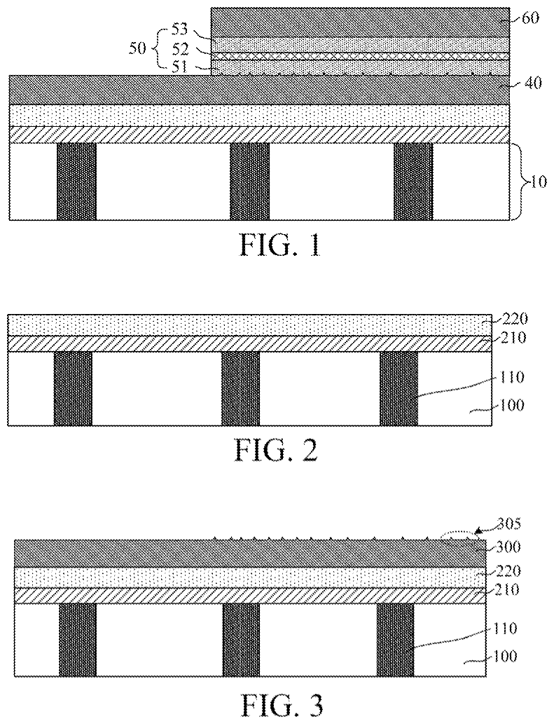

FIG. 2 to FIG. 9 are schematic structural diagrams corresponding to steps in one form of a method for forming a semiconductor structure according to the present disclosure.

Referring to FIG. 2, a base 100 is provided.

The base 100 is used for providing a process platform for forming a subsequent capacitor structure.

In some implementations, the capacitor structure is formed by using a back-end of line. Therefore, the capacitor structure is an MIM capacitor.

For convenience of illustration, only the base 100 of a capacitor region (not shown) is shown, and the capacitor structure is correspondingly formed on the base 100 of the capacitor region.

In some implementations, the base 100 includes a substrate, the substrate being a silicon substrate. In other implementations, the substrate may further be made of other materials such as germanium, silicon germanium, silicon carbide, gallium arsenide, indium gallium, or the like, and the substrate may further be other types of substrates such as a silicon substrate on an insulator, a germanium substrate on the insulator, or the like.

A variety of semiconductor device units, dielectric layers, and metal interconnect structures may further be formed in the base 100. For example, the semiconductor device unit may be a metal oxide semiconductor field effect transistor (MOSFET), a bipolar junction transistor (BJT), a resistor, an inductor, a diode, an optical device, and the like.

In some implementations, a front layer metal interconnect structure 110 is formed in the base 100, a top surface of the front layer metal interconnect structure 110 being exposed from the base 100.

Specifically, a front layer dielectric layer is formed on the substrate, the front layer metal interconnect structure 110 being located in the front layer dielectric layer, and a top of the front layer metal interconnect structure 110 being flush with a top of the front layer dielectric layer.

According to the process situation, one or more stacked metal interconnect layers are formed in the base 100 along a normal direction of a surface of the base 100, for example: a first metal (that is, M1) interconnect layer, a second metal (that is, M2) interconnect layer, and the like. When the metal interconnect layer is multi-layered, an inter-metal dielectric (IMD) layer is formed between two adjacent metal interconnect layers, and the two adjacent metal interconnect layers are electrically connected through a via interconnect structure between the two.

In some implementations, the front layer metal interconnect structure 110 is the first metal interconnect layer, for example. The front layer metal interconnect structure 110 is correspondingly a single damascene structure.

In other implementations, when a multi-layered metal interconnect layer is formed in the base, the front layer metal interconnect structure is correspondingly a dual damascene structure, including a via interconnect (Viax-1) structure and a metal (Mx) interconnect layer above and connected to the via interconnect structure.

To this end, still referring to FIG. 1, the forming method further includes: forming an etch stop layer 210 on the base 100, the etch stop layer 210 covering the front layer metal interconnect structure 110.

In the subsequent process for forming the metal interconnect structure, a surface of the etch stop layer 210 is used to define, in the etching process, a position in which etching stops, thereby reducing a probability of over-etching for the front layer metal interconnect structure 110.

In some implementations, the etch stop layer 210 is made of SiCN. In other implementations, the etch stop layer may further be made of SiCO, SiON, or SiN.

Referring to FIG. 3, a first electrode layer 300 is formed on the base 100.

The first electrode layer 300 is used as a bottom plate of the MIM capacitor.

For this purpose, the first electrode layer 300 is made of a metal material.

Specifically, the first electrode layer 300 is made of nitrided metal, so that the first electrode layer 300 has higher stability, to alleviate the problem of metal ion diffusion.

In some implementations, the first electrode layer 300 is made of titanium nitride (TiN). In other implementations, the first electrode layer may further be made of tantalum nitride (TaN) or tungsten nitride (WN).

It should be noted that the MIM capacitor is formed between adjacent metal interconnect layers in a back-end of line, and therefore the first electrode layer 310 is formed in the capacitor region on the base 100.

Specifically, the step of forming the first electrode layer 300 includes: forming a first electrode material layer (not shown) on the base 100; and patterning the first electrode material layer, and retaining the first electrode material layer located in the capacitor region as the first electrode layer 300.

In some implementations, the electrode material layer is formed by using a physical vapor deposition process. In other implementations, the electrode material layer may also be formed by using an atomic layer deposition process.

In some implementations, the first electrode layer 300 covers the entire capacitor region (not shown). In other implementations, the first electrode layer may also be located in a part of the capacitor region.

In some implementations, the etch stop layer 210 is formed on the base 100, and the first electrode layer 300 is correspondingly formed on the etch stop layer 210.

It should be further noted that the first electrode layer 300 is made of nitrided metal. During the growth of the nitrided metal, the nitrided metal has a relatively apparent columnar crystalline state, and a larger thickness of the first electrode layer 300 leads to a more apparent columnar crystalline state on an upper surface thereof.

Specifically, the nitrided metal layer benefits from a flat surface of the base 100 when growing on the base 100, and the upper surface of the nitrided metal layer grows in a preferred crystal direction. Therefore, the upper surface of the first electrode layer 300 easily has a columnar crystal 305.

Still referring to FIG. 2, it should be noted that, before the electrode material layer is formed, the forming method further includes: forming an interlayer dielectric layer 220 on the etch stop layer 210.

The interlayer dielectric layer 220 is used as a transition layer between the first electrode layer 300 and the etch stop layer 210, to reduce the probability of delamination or crack of the first electrode layer 300 due to stress.

The interlayer dielectric layer 220 is further used to implement isolation between the front layer metal interconnect structure 110 and the subsequently formed metal interconnect structure.

To this end, in some implementations, the interlayer dielectric layer 220 is made of silicon oxide.

In other implementations, the interlayer dielectric layer may be further made of a low-k dielectric material (the low-k dielectric material is a dielectric material having a relative dielectric constant greater than or equal to 2.6 and less than or equal to 3.9), or an ultra-low-k dielectric material (the ultra-low-k dielectric material is a dielectric material having a relative dielectric constant less than 2.6), for example, SiOH, SiOCH, FSG, BSG, PSG, BPSG, hydrogenated silsesquioxane, or methylsilsesquioxane.

Correspondingly, as shown in FIG. 3, in some implementations, the first electrode layer 300 is formed on the interlayer dielectric layer 220.

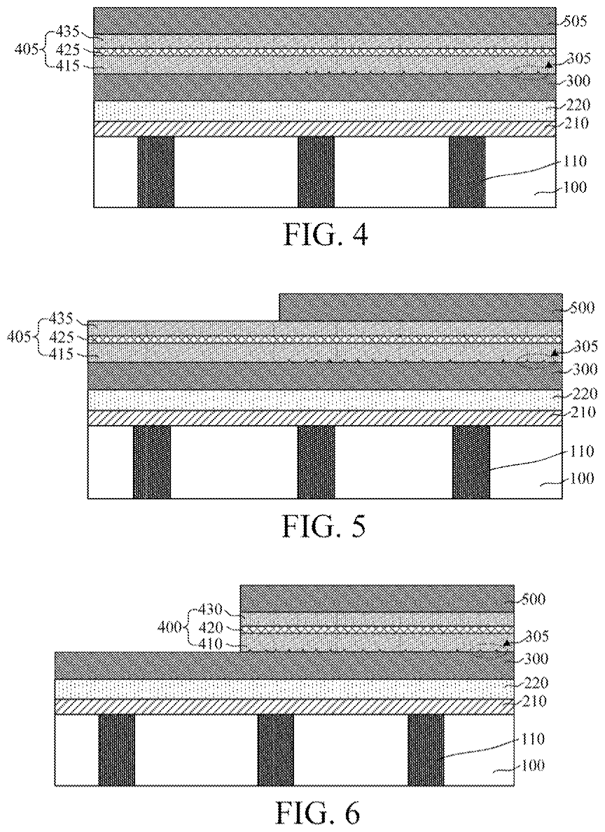

Referring to FIG. 4 to FIG. 6, a capacitor dielectric layer 400 (as shown in FIG. 6) with a stacked structure is formed on the first electrode layer 300, and a second electrode layer 500 (as shown in FIG. 5) on the capacitor dielectric layer 400 is formed. The capacitor dielectric layer 400 includes a bottom high-k dielectric layer 410 (as shown in FIG. 6), a leakage-proof dielectric layer 420 (as shown in FIG. 6), and a top high-k dielectric layer 430 (as shown in FIG. 6) that are sequentially stacked from bottom to top. The bottom high-k dielectric layer 410 and the top high-k dielectric layer 430 have a preset total deposition thickness, and a proportion of a deposition thickness of the bottom high-k dielectric layer 410 to the preset total deposition thickness is greater than a proportion of a deposition thickness of the top high-k dielectric layer 430 to the preset total deposition thickness.

In some implementations, according to a preset capacitance value of the capacitor structure, the preset total deposition thickness can be determined, and the preset total deposition thickness is a total value of the deposition thicknesses of the bottom high-k dielectric layer 410 and the top high-k dielectric layer 430. The deposition thickness of the bottom high-k dielectric layer 410 is: a physical thickness during formation of the bottom high-k dielectric layer 410. The deposition thickness of the top high-k dielectric layer 430 is: a physical thickness during formation of the top high-k dielectric layer 430.

In some implementations, the capacitor dielectric layer 400 has an asymmetric structure, that is, the deposition thickness of the bottom high-k dielectric layer 410 is greater than the deposition thickness of the top high-k dielectric layer 430, so that the proportion of the deposition thickness of the bottom high-k dielectric layer 410 to the preset total deposition thickness is greater than the proportion of the deposition thickness of the top high-k dielectric layer 430 to the preset total deposition thickness.

At the interface between the first electrode layer 300 and the bottom high-k dielectric layer 410, the bottom high-k dielectric layer 410 easily reacts with the first electrode layer 300 to form a reaction layer, thereby consuming a part of the bottom high-k dielectric layer 410 in thickness, so that the effective thickness (that is, the thickness of the high-k dielectric material) of the bottom high-k dielectric layer 410 is reduced. Moreover, the upper surface of the first electrode layer 300 is likely to generate a columnar crystal 305. After the bottom high-k dielectric layer 410 is formed on the surface of the first electrode layer 300, the bottom high-k dielectric layer 410 will be first filled in the gaps between the columnar crystals 305 and react with the first electrode layer 300 to form a reaction layer. For example, when the first electrode layer 300 is made of titanium nitride, and the bottom high-k dielectric layer 410 is made of hafnium oxide, the bottom high-k dielectric layer 410 reacts with the first electrode layer 300 to generate a reaction layer of TiOₓN_{y}.

The probability of crystallization of the reaction layer is low, and a difference between the deposition thickness of the bottom high-k dielectric layer 410 and the thickness of the reaction layer is the effective thickness of the bottom high-k dielectric layer 410. A larger effective thickness of the bottom high-k dielectric layer 410 leads to a greater possibility that the bottom high-k dielectric layer 410 is to crystallize, and the thickness consumed in the bottom high-k dielectric layer 410 has less effect on the crystallization problem. Therefore, the proportion of the deposition thickness of the bottom high-k dielectric layer 410 to the preset total deposition thickness is greater than the deposition thickness of the top high-k dielectric layer 430 to the preset total deposition thickness to adjust respective proportions of the bottom high-k dielectric layer 410 and the top high-k dielectric layer 430 to the total thickness of the capacitor dielectric layer 400. When the preset total deposition thickness is unchanged, the deposition thickness of the bottom high-k dielectric layer 410 is increased, and the deposition thickness of the top high-k dielectric layer 430 is decreased, so that the effective thicknesses of the bottom high-k dielectric layer 410 and the top high-k dielectric layer 430 are both small, thereby alleviating the crystallization problem of the bottom high-k dielectric layer 410 and the top high-k dielectric layer 430, and correspondingly alleviating the leakage current problem caused by crystallization. Accordingly, a breakdown voltage (VBD) of the capacitor dielectric layer is increased, and the reliability of the capacitor structure is improved, for example, the performance of TDDB.

In other words, because a part of the bottom high-k dielectric layer 410 in thickness is consumed, even if the deposition thickness of the bottom high-k dielectric layer 410 is increased, the effective thickness of the bottom high-k dielectric layer 410 is still small, and the bottom high-k dielectric layer 410 is less likely to crystallize. However, the deposition thickness of the bottom high-k dielectric layer 410 is increased, the deposition thickness of the top high-k dielectric layer 430 is correspondingly decreased, and the top high-k dielectric layer 430 is also less likely to crystallize.

Furthermore, it may be learned from the capacitance formula that, a capacitance value of a single capacitor structure is inversely proportional to the thickness of the capacitor dielectric layer 400. Therefore, in some implementations, the deposition thickness of the top high-K dielectric layer 430 is reduced while the deposition thickness of the bottom high-K dielectric layer 410 is increased, so that the preset total deposition thickness does not change, thereby facilitating reduction in the influence on the capacitance value of the capacitor structure.

The capacitor dielectric layer 400 is used as an insulation layer in an MIM capacitor.

In some implementations, the capacitor dielectric layer 400 includes a bottom high-k dielectric layer 410, a leakage-proof dielectric layer 420, and a top high-k dielectric layer 430 that are sequentially stacked from bottom to top.

After the deposition thickness of the high-k dielectric layer reaches a certain value, formation quality thereof is likely to deteriorate. As a result, the capacitor dielectric layer 400 has better formation quality while the thickness of the capacitor dielectric layer 400 meets the performance requirements of the capacitor structure through the bottom high-k dielectric layer 410 and the top high-k dielectric layer 430.

The bottom high-k dielectric layer 410 and the top high-k dielectric layer 430 are both made of a high-k dielectric material. The high-k dielectric material refers to a dielectric material having a relative dielectric constant greater than a relative dielectric constant of silicon oxide. By choosing the high-k dielectric material, it can help increase the capacitance density of the MIM capacitor.

The bottom high-k dielectric layer 410 is made of a material including titanium oxide, cobalt oxide, nickel oxide, copper oxide, zinc oxide, zirconium oxide, hafnium oxide, tantalum oxide, tungsten oxide, strontium titanate (SrTiO₃), strontium zirconate (SrZrO₃), or strontium ruthenate (SrRuO₃). In some implementations, the bottom high-k dielectric layer 410 is made of hafnium oxide.

The top high-k dielectric layer 430 is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate. In some implementations, the top high-k dielectric layer 430 is made of hafnium oxide.

It should be noted that, a proportion of the deposition thickness of the top high-k dielectric layer 430 to the deposition thickness of the bottom high-k dielectric layer 410 should be neither too small nor too large. If the proportion is too large, the deposition thickness of the top high-k dielectric layer 430 is still large, and it is difficult to significantly alleviate the crystallization problem of the top high-k dielectric layer 430. If the proportion is too small, the deposition thickness of the bottom high-k dielectric layer 410 may be too large, thereby easily causing the crystallization problem of the bottom high-k dielectric layer 410. To this end, in some implementations, a proportion of the deposition thickness of the top high-k dielectric layer 430 to the deposition thickness of the bottom high-k dielectric layer 410 is 0.5 to 0.9. For example, the proportion is 0.6, 0.7, or 0.8

It should be further noted that the deposition thickness of the bottom high-k dielectric layer 410 should be neither too small nor too large. If the deposition thickness of the bottom high-k dielectric layer 410 is too small, it is difficult to compensate for a thickness required for the bottom high-k dielectric layer 410 to fill the gap between the columnar crystals 305, and a thickness consumed for reaction of the bottom high-k dielectric layer 410 and the first electrode layer 300. In addition, the deposition thickness of the top high-k dielectric layer 430 is still relatively large, so that it is difficult to significantly alleviate the crystallization problem of the top high-k dielectric layer 430. If the deposition thickness of the bottom high-k dielectric layer 410 is too large, the crystallization problem of the bottom high-k dielectric layer 410 may be easily caused. Therefore, in some implementations, the deposition thickness of the bottom high-k dielectric layer 410 is 1.5 nm to 4 nm. For example, the deposition thickness of the bottom high-k dielectric layer 410 is 2 nm, 2.5 nm, 3 nm, or 3.5 nm.

By forming the leakage-proof dielectric layer 420 between the two high-k dielectric layers, it can help reduce the leakage current of the capacitor structure and improve the resistive breakdown resistance of the capacitor structure.

The material of the leakage-proof dielectric layer 420 is set as follows. The material of the leakage-proof dielectric layer 420 has a relatively large band gap, which can help reduce the leakage current.

Therefore, the leakage-proof dielectric layer 420 is made of a material including aluminum oxide, silicon oxide, or silicon nitride.

In some implementations, the leakage-proof dielectric layer 420 is made of aluminum oxide. A larger band gap made of aluminum oxide makes the capacitor dielectric layer 400 less prone to electric leakage and breakdown, and the dielectric constant of aluminum oxide is also larger, which can help increase the capacitance density of the capacitor structure.

It should be noted that the top high-k dielectric layer 430 is formed on the leakage-proof dielectric layer 420, columnar crystals cannot be formed on the top surface of the leakage-proof dielectric layer 420, and the top high-k dielectric layer 430 is less prone to reaction with the leakage-proof dielectric layer 420.

The second electrode layer 500 is used as a top plate of the MIM capacitor.

For this purpose, the second electrode layer 500 is made of a metal material.

Specifically, the second electrode layer 500 is made of nitrided metal. In some implementations, the second electrode layer 500 is made of TiN. In other implementations, the second electrode layer may further be made of TaN or WN.

For details of the second electrode layer 500, reference may be made to the corresponding description for the first electrode layer 300, and details are not described herein again.

In some implementations, the second electrode layer 500 is formed above a part of the first electrode layer 300, and the capacitor dielectric layer 400 is formed between the second electrode layer 500 and the first electrode layer 300. The second electrode layer 500 exposes the first electrode layer 300 to facilitate the subsequent formation of a first conductive pillar connected to a top of the first electrode layer 300 on one side of the second electrode layer 500 and a second conductive pillar connected to a top of the second electrode layer 500, respectively.

Therefore, in some implementations, after the second electrode layer 500 is formed, the capacitor dielectric layer 400 is formed.

Correspondingly, as shown in FIG. 4, after the first electrode layer 300 is formed on the base 100, and before the capacitor dielectric layer 400 is formed on the first electrode layer 300 and a second electrode layer 500 on the capacitor dielectric layer 400 is formed, the forming method further includes: forming a capacitor dielectric film 405 covering the stacked structure of the first electrode layer 300, the capacitor dielectric film 405 including a bottom high-k dielectric film 415, a leakage-proof dielectric material layer 425, and a top high-k dielectric film 435 that are sequentially stacked from bottom to top, the bottom high-k dielectric film 415 and the top high-k dielectric film 435 having a preset total deposition thickness, and a proportion of a deposition thickness of the bottom high-k dielectric film 415 to the preset total deposition thickness being greater than a proportion of a deposition thickness of the top high-k dielectric film 435 to the preset total deposition thickness.

The capacitor dielectric film 405 is configured to prepare for subsequent formation of a capacitor dielectric layer.

Specifically, the bottom high-k dielectric film 415 is used to prepare for forming a bottom high-k dielectric layer, the leakage-proof dielectric material layer 425 is used to prepare for subsequent formation of a leakage-proof dielectric layer, and the top high-k dielectric film 435 is used to prepare for subsequent formation of a top high-k dielectric layer.

In some implementations, the bottom high-k dielectric film 415 is made of hafnium oxide, the leakage-proof dielectric material layer 425 is made of silicon nitride, and the top high-k dielectric film 435 is made of hafnium oxide.

In some implementations, the capacitor dielectric film 405 is formed using an atomic layer deposition process. The atomic layer deposition process includes performing a plurality of atomic layer deposition cycles to form the capacitor dielectric film 405 of a required thickness. By using the atomic layer deposition process, the thickness uniformity of the capacitor dielectric film 405 can be improved, and a thickness of each film layer in the capacitor dielectric film 405 can be accurately controlled.

In other implementations, the capacitor dielectric film may further be formed by using other deposition processes, for example, a plasma chemical vapor deposition process, and the like.

With reference to FIG. 4 and FIG. 5, the step of forming the second electrode layer 500 correspondingly includes: forming an electrode film 505 (as shown in FIG. 4) covering the capacitor dielectric film 405; and patterning the electrode film 505 to form the second electrode layer 500 above a part of the first electrode layer 300.

In some implementations, the electrode film 505 is formed by using a physical vapor deposition process. In other implementations, the electrode film may also be formed by using an atomic layer deposition process.

In some implementations, the electrode film 505 is patterned by using a dry etching process (for example, an anisotropic dry etching process). The dry etching process has anisotropic etching characteristics, which facilitates improvement of profile quality of a side wall of the second electrode layer 500.

Specifically, the dry etching process is the plasma dry etching process.

Referring to FIG. 6, the step of forming the capacitor dielectric layer 400 includes: after the second electrode layer 500 is formed, removing the capacitor dielectric film 405 (as shown in FIG. 5) exposed from the second electrode layer 500, and retaining, as the capacitor dielectric layer 400, the capacitor dielectric film 405 remaining between the second electrode layer 500 and the first electrode layer 300.

In some implementations, the capacitor dielectric film 405 exposed from the second electrode layer 500 is removed by etching by using a dry etching process (for example, an anisotropic dry etching process). The dry etching process has anisotropic etching characteristics, which facilitates improvement of profile quality of a side wall of the capacitor dielectric layer 400.

Specifically, the dry etching process is the plasma dry etching process.

In some other implementations, in the step of forming a first electrode layer on the base, the first electrode layer covers a base of a part of a capacitor region, and the capacitor dielectric layer conformally covers a top and a side wall of the first electrode layer. Correspondingly, the second electrode layer covers a top and a side wall of the capacitor dielectric layer, and extends to cover the base exposed from the first electrode layer.

In some implementations, the capacitor dielectric layer is formed not only on the top of the first electrode layer, but also on the side wall of the first electrode layer, which increases the effective area between the top plate and the bottom plate in the MIM capacitor, so that the second electrode layer, the first electrode layer, and the capacitor dielectric layer located on the top of the first electrode layer form a capacitor, and the second electrode layer, the first electrode layer, and the capacitor dielectric layer located on the side wall of the first electrode layer form another four capacitors (that is, four side wall capacitors). The formed capacitor structure includes five parallel capacitors, and the total capacitance value of the parallel capacitors is equal to the sum of the capacitance values. Therefore, under other same conditions such as the same base area, the capacitance density of the capacitor structure is increased, so that the performance of the MIM capacitor can meet the application requirements.

It should be noted that the foregoing interlayer dielectric layer 220 formed on the etch stop layer 210 is used as the first interlayer dielectric layer.

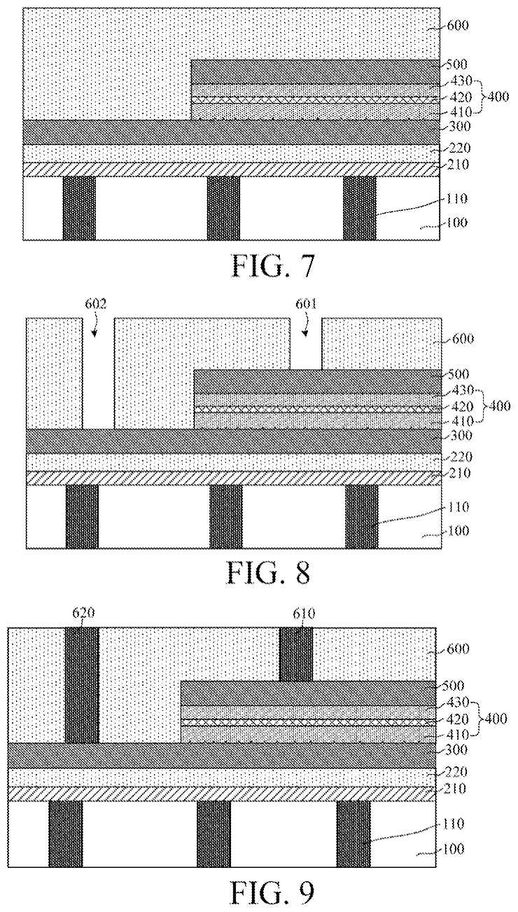

With reference to FIG. 7, after the capacitor dielectric layer 400 is formed on the first electrode layer 300, and a second electrode layer 500 on the capacitor dielectric layer 400 is formed, the forming method further includes: forming a second interlayer dielectric layer 600 covering the second electrode layer 500, the capacitor dielectric layer 400, and the first electrode layer 300.

The second interlayer dielectric layer 600 is used to provide a process platform for subsequently forming conductive pillars electrically connected to the first electrode layer 300 and the second electrode layer 500.

In some implementations, since the MIM capacitor is formed on the metal interconnect structure in the back-end of line, the second interlayer dielectric layer 340 is further used as a flat layer to improve the flatness of a top surface of the subsequent inter metal dielectric layer.

In some implementations, the second interlayer dielectric layer 600 is made of silicon oxide.

It should be noted that, compared with the material (for example, a low-k dielectric material or an ultra-low-k dielectric material) of the inter metal dielectric layer, the density of the second interlayer dielectric layer 600 is higher, so that the second interlayer dielectric layer 600 has relatively high top surface flatness after the planarization process.

Specifically, the second interlayer dielectric layer 600 is formed by sequentially performing a deposition process and a planarization process.

In some implementations, the deposition process is a chemical vapor deposition process.

In other implementations, the second interlayer dielectric layer is an inter metal dielectric layer, and is further used to provide a process platform for subsequently forming the metal interconnect structure.

Referring to FIG. 8, a first opening 602 is formed in the second interlayer dielectric layer 600 on the side of the second electrode layer 500, the first opening 602 exposing the top of the first electrode layer 300. A second opening 601 is formed in the second interlayer dielectric layer 600 on the top of the second electrode layer 500, the second opening 601 exposing the top of the second electrode layer 500.

The first opening 602 is used to provide a space position for the subsequent formation of a first conductive pillar electrically connected to the first electrode layer 300, and the second opening 601 is used to provide a spatial position for the subsequent formation of a second conductive pillar electrically connected to the second electrode layer 500.

In some implementations, the second interlayer dielectric layer 600 is etched by using a mask, to form the first opening 602 and the second opening 601.

In some implementations, in order to improve the profile quality of a side wall of the first opening 602 and the second opening 601, an anisotropic dry etching process is used to etch the second interlayer dielectric layer 600, for example: the step of etching is performed by using a plasma dry etching process.

Specifically, the first opening 602 and the second opening 601 may be formed in the dual damascene process for forming the metal interconnect structure.

In some implementations, the second interlayer dielectric layer 600 is etched by using the anisotropic dry etching process. In other implementations, an etching process combining dry etching and wet etching may further be used for etching.

It should be noted that since the second electrode layer 500 exposes the first electrode layer 300 and the capacitor dielectric layer 400 is formed between the second electrode layer 500 and the first electrode layer 300, only the second interlayer dielectric layer 600 is etched in the process for forming the first opening 602 and the second opening 601, and the etching process is relatively simple.

In some implementations, the first opening 602 is formed in the second interlayer dielectric layer 600 on the side of the second electrode layer 500, and the second opening 601 is formed in the second dielectric layer 600 on the top of the second electrode layer 500, so that there is a certain distance between the first opening 602 and the second opening 601, thereby increasing the process window for forming the first opening 602 and the second opening 601 and helping reduce process risks.

Referring to FIG. 9, a first conductive pillar 620 is formed in the first opening 602 (as shown in FIG. 8), and a second conductive pillar 610 is formed in the second opening 601 (as shown in FIG. 8).

The first conductive pillar 620 is used as an external electrode of the first electrode layer 300, and the second conductive pillar 610 is used as an external electrode of the second electrode layer 500, thereby implementing the electrical connection between the MIM capacitor and an external circuit.

In some implementations, the first conductive pillar 620 and the second conductive pillar 610 are made of copper. In other implementations, other conductive materials may further be used, for example, aluminum or tungsten.

In some implementations, after the first opening 602 and the second opening 601 are filled with the conductive material, a planarization process is performed on the conductive material, the conductive material in the first opening 602 is retained as the first conductive pillar 620, and the conductive material in the second opening 601 is retained as the second conductive pillar 610.

Specifically, the first opening 602 and the second opening 601 are filled with the conductive material by using an electroplating process.

Correspondingly, the present disclosure further provides a semiconductor structure. Still referring to FIG. 9, a schematic structural diagram of an embodiment of a semiconductor structure according to the present disclosure is shown.

The semiconductor structure includes: a base 100; a first electrode layer 300 located on the base 100; a capacitor dielectric layer 400 with a stacked structure located on the first electrode layer 300, the capacitor dielectric layer 400 including a bottom high-k dielectric layer 410, a leakage-proof dielectric layer 420, and a top high-k dielectric layer 430 that are sequentially stacked from bottom to top, the bottom high-k dielectric layer 410 and the top high-k dielectric layer 430 having a preset total deposition thickness, and a proportion of a deposition thickness of the bottom high-k dielectric layer 410 to the preset total deposition thickness being greater than a proportion of a deposition thickness of the top high-k dielectric layer 430 to the preset total deposition thickness; and a second electrode layer 500 located on the capacitor dielectric layer 400.

In some implementations, the capacitor structure is formed by using a back-end of line. Therefore, the capacitor structure is an MIM capacitor.

According to a preset capacitance value of the capacitor structure, the preset total deposition thickness is determined, and the preset total deposition thickness is a total value of the deposition thicknesses of the bottom high-k dielectric layer 410 and the top high-k dielectric layer 430. The deposition thickness of the bottom high-k dielectric layer 410 is: a physical thickness during formation of the bottom high-k dielectric layer 410. The deposition thickness of the top high-k dielectric layer 430 is: a physical thickness during formation of the top high-k dielectric layer 430.

In some implementations, the capacitor dielectric layer 400 has an asymmetric structure, and the bottom high-k dielectric layer 410 has the deposition thickness greater than the deposition thickness of the top high-k dielectric layer 430.

At the interface between the first electrode layer 300 and the bottom high-k dielectric layer 410, the bottom high-k dielectric layer 410 easily reacts with the first electrode layer 300, thereby consuming a part of the bottom high-k dielectric layer 410 in thickness, so that the effective thickness (that is, the thickness of the high-k dielectric material) of the bottom high-k dielectric layer 410 is reduced. Moreover, the upper surface of the first electrode layer 300 is likely to generate a columnar crystal 305. After the bottom high-k dielectric layer 410 is formed on the surface of the first electrode layer 300, the bottom high-k dielectric layer 410 will be first filled in the gaps between the columnar crystals 305 and react with the first electrode layer 300. The bottom high-k dielectric layer 410 reacts with the first electrode layer 300 to form a reaction layer. For example, when the first electrode layer 300 is made of titanium nitride, and the bottom high-k dielectric layer 410 is made of hafnium oxide, the bottom high-k dielectric layer 410 reacts with the first electrode layer 300 to generate a reaction layer of TiOₓN_{y}.

The probability of crystallization of the reaction layer is low, and a difference between the deposition thickness of the bottom high-k dielectric layer 410 and the thickness of the reaction layer is the effective thickness of the bottom high-k dielectric layer 410. A larger effective thickness of the bottom high-k dielectric layer 410 leads to a greater possibility that the bottom high-k dielectric layer 410 is to crystallize, and the thickness consumed in the bottom high-k dielectric layer 410 has less effect on the crystallization problem. Therefore, the proportion of the deposition thickness of the bottom high-k dielectric layer 410 to the preset total deposition thickness is greater than the deposition thickness of the top high-k dielectric layer 430 to the preset total deposition thickness to adjust respective proportions of the bottom high-k dielectric layer 410 and the top high-k dielectric layer 430 to the total thickness of the capacitor dielectric layer 400. When the preset total deposition thickness is unchanged, the deposition thickness of the bottom high-k dielectric layer 410 is increased, and the deposition thickness of the top high-k dielectric layer 430 is decreased, so that the effective thicknesses of the bottom high-k dielectric layer 410 and the top high-k dielectric layer 430 are both small, thereby alleviating the crystallization problem of the bottom high-k dielectric layer 410 and the top high-k dielectric layer 430, and correspondingly alleviating the leakage current problem caused by crystallization. Accordingly, a breakdown voltage (VBD) of the capacitor dielectric layer is increased, and the reliability of the capacitor structure is improved, for example, the performance of TDDB.

In other words, because a part of the bottom high-k dielectric layer 410 in thickness is to be converted into the reaction layer, even if the deposition thickness of the bottom high-k dielectric layer 410 is increased, the effective thickness of the bottom high-k dielectric layer 410 is still small, and the bottom high-k dielectric layer 410 is less likely to crystallize. However, the deposition thickness of the bottom high-k dielectric layer 410 is increased, the deposition thickness of the top high-k dielectric layer 430 is correspondingly decreased, and the top high-k dielectric layer 430 is also less likely to crystallize.

Furthermore, it may be learned from the capacitance formula that, a capacitance value of a single capacitor structure is inversely proportional to the thickness of the capacitor dielectric layer 400. Therefore, in some implementations, the deposition thickness of the top high-K dielectric layer 430 is reduced while the deposition thickness of the bottom high-K dielectric layer 410 is increased, so that the preset total deposition thickness does not change, thereby facilitating reduction in the influence on the capacitance value of the capacitor structure.

In some implementations, for convenience of illustration, only the base 100 of a capacitor region (not shown) is shown, and the capacitor structure is correspondingly formed on the base 100 of the capacitor region.

In some implementations, the base 100 includes a substrate, the substrate being a silicon substrate. In other implementations, the substrate may further be made of other materials such as germanium, silicon germanium, silicon carbide, gallium arsenide, indium gallium, or the like, and the substrate may further be other types of substrates such as a silicon substrate on an insulator, a germanium substrate on the insulator, or the like.

A variety of semiconductor device units, dielectric layers, and metal interconnect structures may further be formed in the base 100. For example, the semiconductor device unit may be a metal oxide semiconductor field effect transistor, a bipolar junction transistor, a resistor, an inductor, a diode, an optical device, and the like.

In some implementations, a front layer metal interconnect structure 110 is formed in the base 100, a top surface of the front layer metal interconnect structure 110 being exposed from the base 100. Specifically, a front layer dielectric layer is formed on the substrate, the front layer metal interconnect structure 110 being located in the front layer dielectric layer, and a top of the front layer metal interconnect structure 110 being flush with a top of the front layer dielectric layer.

According to the process situation, one or more stacked metal interconnect layers are formed in the base 100 along a normal direction of a surface of the base 100, for example: a first metal interconnect layer, a second metal interconnect layer, and the like. When the metal interconnect layer is multi-layered, an inter-metal dielectric layer is formed between two adjacent metal interconnect layers, and the two adjacent metal interconnect layers are electrically connected through a via interconnect structure between the two.

In some implementations, the front layer metal interconnect structure 110 is the first metal interconnect layer, for example. The front layer metal interconnect structure 110 is correspondingly a single damascene structure. In other implementations, when a multi-layered metal interconnect layer is formed in the base, the front layer metal interconnect structure is correspondingly a dual damascene structure, including a via interconnect structure and a metal interconnect layer above and connected to the via interconnect structure.

In some implementations, the semiconductor structure further includes: an etch stop layer 210 on the base 100, the etch stop layer 210 covering the front layer metal interconnect structure 110.

A surface of the etch stop layer 210 is used to define, in the etching process, a position in which etching stops, thereby reducing a probability of over-etching for the front layer metal interconnect structure 110.

In some implementations, the etch stop layer 210 is made of SiCN. In other implementations, the etch stop layer may further be made of SiCO, SiON, or SiN.

The first electrode layer 300 is used as a bottom plate of the MIM capacitor. For this purpose, the first electrode layer 300 is made of a metal material. Specifically, the first electrode layer 300 is made of nitrided metal, so that the first electrode layer 300 has higher stability, to alleviate the problem of metal ion diffusion.

In some implementations, the first electrode layer 300 is made of titanium nitride (TiN). In other implementations, the first electrode layer may further be made of tantalum nitride (TaN) or tungsten nitride (WN).

It should be noted that the MIM capacitor is formed between adjacent metal interconnect layers in a back-end of line, and therefore the first electrode layer 310 is formed in the capacitor region on the base 100.

In some implementations, the first electrode layer 300 covers the entire capacitor region (not shown). In other implementations, the first electrode layer may also be located in a part of the capacitor region.

In some implementations, the etch stop layer 210 is formed on the base 100, and the first electrode layer 300 is correspondingly formed on the etch stop layer 210.

It should be further noted that the first electrode layer 300 is made of nitrided metal. During the growth of the nitrided metal, the nitrided metal has a relatively apparent columnar crystalline state, and a larger thickness of the first electrode layer 300 leads to a more apparent columnar crystalline state on an upper surface thereof. Specifically, the nitrided metal layer benefits from a flat surface of the base 100 when growing on the base 100, and the upper surface of the nitrided metal layer grows in a preferred crystal direction. Therefore, the upper surface of the first electrode layer 300 easily has a columnar crystal 305.

In some implementations, the semiconductor structure further includes: an interlayer dielectric layer 220 located on the etch stop layer 210.

The interlayer dielectric layer 220 is used as a transition layer between the first electrode layer 300 and the etch stop layer 210, to reduce the probability of delamination or crack of the first electrode layer 300 due to stress.

The interlayer dielectric layer 220 is further used to implement isolation between the front layer metal interconnect structure 110 and the subsequently formed metal interconnect structure. In some implementations, the interlayer dielectric layer 220 is made of silicon oxide. In other implementations, the interlayer dielectric layer may further be made of a low-K dielectric material or an ultra-low-K dielectric material, for example, SiOH, SiOCH, FSG, BSG, PSG, BPSG, hydrogenated silsesquioxane, or methylsilsesquioxane.

Correspondingly, the first electrode layer 300 is located on the interlayer dielectric layer 220.

The capacitor dielectric layer 400 is used as an insulation layer in an MIM capacitor. In some implementations, the capacitor dielectric layer 400 includes a bottom high-k dielectric layer 410, a leakage-proof dielectric layer 420, and a top high-k dielectric layer 430 that are sequentially stacked from bottom to top.

After the deposition thickness of the high-k dielectric layer reaches a certain value, formation quality thereof is likely to deteriorate. As a result, the capacitor dielectric layer 400 has better formation quality while the thickness of the capacitor dielectric layer 400 meets the performance requirements of the capacitor structure through the bottom high-k dielectric layer 410 and the top high-k dielectric layer 430.

The bottom high-k dielectric layer 410 and the top high-k dielectric layer 430 are both made of a high-k dielectric material. By choosing the high-k dielectric material, it can help increase the capacitance density of the MIM capacitor.

The bottom high-k dielectric layer 410 is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate. In some implementations, the bottom high-k dielectric layer 410 is made of hafnium oxide.

The top high-k dielectric layer 430 is made of a material including titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate. In some implementations, the top high-k dielectric layer 430 is made of hafnium oxide.

It should be noted that, a proportion of the deposition thickness of the top high-k dielectric layer 430 to the deposition thickness of bottom high-k dielectric layer 410 should be neither too small nor too large. If the proportion is too large, the deposition thickness of the top high-k dielectric layer 430 is still large, and it is difficult to significantly alleviate the crystallization problem of the top high-k dielectric layer 430. If the proportion is too small, the deposition thickness of the bottom high-k dielectric layer 410 may be too large, thereby easily causing the crystallization problem of the bottom high-k dielectric layer 410. To this end, In some implementations, a proportion of the deposition thickness of the top high-k dielectric layer 430 to the deposition thickness of the bottom high-k dielectric layer 410 is 0.5 to 0.9. For example, the proportion is 0.6, 0.7, or 0.8

It should be further noted that the deposition thickness of the bottom high-k dielectric layer 410 should be neither too small nor too large. If the deposition thickness of the bottom high-k dielectric layer 410 is too small, it is difficult to compensate for a thickness required for the bottom high-k dielectric layer 410 to fill the gap between the columnar crystals 305, and a thickness consumed for reaction of the bottom high-k dielectric layer 410 and the first electrode layer 300. In addition, the deposition thickness of the top high-k dielectric layer 430 is still relatively large, so that it is difficult to significantly alleviate the crystallization problem of the top high-k dielectric layer 430. If the deposition thickness of the bottom high-k dielectric layer 410 is too large, the crystallization problem of the bottom high-k dielectric layer 410 may be easily caused. Therefore, in some implementations, the deposition thickness of the bottom high-k dielectric layer 410 is 1.5 nm to 4 nm. For example, the deposition thickness of the bottom high-k dielectric layer 410 is 2 nm, 2.5 nm, 3 nm, or 3.5 nm.

By forming the leakage-proof dielectric layer 420 between the two high-k dielectric layers, it can help reduce the leakage current of the capacitor structure and improve the resistive breakdown resistance of the capacitor structure. The material of the leakage-proof dielectric layer 420 is set as follows. The material of the leakage-proof dielectric layer 420 has a relatively large band gap, which can help reduce the leakage current.

Therefore, the leakage-proof dielectric layer 420 is made of a material including aluminum oxide, silicon oxide, or silicon nitride. In some implementations, the leakage-proof dielectric layer 420 is made of aluminum oxide.

The second electrode layer 500 is used as a top plate of the MIM capacitor. For this purpose, the second electrode layer 500 is made of a metal material. Specifically, the second electrode layer 500 is made of nitrided metal. In some implementations, the second electrode layer 500 is made of TiN. In other implementations, the second electrode layer may further be made of TaN or WN.

For details of the second electrode layer 500, reference may be made to the corresponding description for the first electrode layer 300, and details are not described herein again.

In some implementations, the second electrode layer 500 is located above a part of the first electrode layer 300, and the capacitor dielectric layer 400 is formed between the second electrode layer 500 and the first electrode layer 300.

In other implementations, the first electrode layer covers a base of a part of a capacitor region, and the capacitor dielectric layer conformally covers a top and a side wall of the first electrode layer. Correspondingly, the second electrode layer covers a top and a side wall of capacitor dielectric layer, and extends to cover the base exposed from the first electrode layer. In some implementations, the capacitor dielectric layer is formed not only on the top of the first electrode layer, but also on the side wall of the first electrode layer, which increases the effective area between the top plate and the bottom plate in the MIM capacitor, so that the second electrode layer, the first electrode layer, and the capacitor dielectric layer located on the top of the first electrode layer form a capacitor, and the second electrode layer, the first electrode layer, and the capacitor dielectric layer located on the side wall of the first electrode layer form another four capacitors (that is, four side wall capacitors). The formed capacitor structure includes five parallel capacitors, and the total capacitance value of the parallel capacitors is equal to the sum of the capacitance values. Therefore, under other same conditions such as the same base area, the capacitance density of the capacitor structure is increased, so that the performance of the MIM capacitor can meet the application requirements.

It should be noted that the foregoing interlayer dielectric layer 220 formed on the etch stop layer 210 is used as the first interlayer dielectric layer.

The semiconductor structure further includes: a second interlayer dielectric layer 600 covering the second electrode layer 500, the capacitor dielectric layer 400, and the first electrode layer 300.

The second interlayer dielectric layer 600 is used to provide a process platform for forming conductive pillars electrically connected to the first electrode layer 300 and the second electrode layer 500.

In some implementations, since the MIM capacitor is formed on the metal interconnect structure in the back-end of line, the second interlayer dielectric layer 340 is further used as a flat layer to improve the flatness of a top surface of the subsequent inter metal dielectric layer.

In some implementations, the second interlayer dielectric layer 600 is made of silicon oxide. Compared with the material (for example, a low-k dielectric material or an ultra-low-k dielectric material) of the inter metal dielectric layer, the density of the second interlayer dielectric layer 600 is higher, so that the second interlayer dielectric layer 600 has relatively high top surface flatness after the planarization process.

In other implementations, the second interlayer dielectric layer is an inter metal dielectric layer, and is further used to provide a process platform for subsequently forming the metal interconnect structure.

In some implementations, the semiconductor structure further includes: a first conductive pillar 620 penetrating through the second interlayer dielectric layer 600 on one side of the second electrode layer 500, the first conductive pillar 620 being electrically connected to the top of the first electrode layer 300; and a second conductive pillar 610 penetrating through the second dielectric layer 600 on a top of the second electrode layer 500, the second conductive pillar 610 being electrically connected to the top of the second electrode layer 500.

The first conductive pillar 620 is used as an external electrode of the first electrode layer 300, and the second conductive pillar 610 is used as an external electrode of the second electrode layer 500, thereby implementing the electrical connection between the MIM capacitor and an external circuit.

It should be noted that since the second electrode layer 500 exposes the first electrode layer 300 and the capacitor dielectric layer 400 is located between the second electrode layer 500 and the first electrode layer 300, only the second interlayer dielectric layer 600 is etched in the process for forming the first conductive pillar 620 and the second conductive pillar 610, and the etching process is relatively simple. Moreover, there is a certain distance between the first conductive pillar 620 and the second conductive pillar 610, thereby increasing the process window for forming the first conductive pillar 620 and the second conductive pillar 610, and facilitating reduction in the process risk.

In some implementations, the first conductive pillar 620 and the second conductive pillar 610 are made of copper. In other implementations, other conductive materials may further be used, for example, aluminum or tungsten.

Although embodiments and implementations of the present disclosure are disclosed and described above, the present disclosure is not limited thereto. Any person skilled in the art can make various changes and modifications without departing from the spirit and the scope of the present disclosure, and therefore the protection scope of the present disclosure should be subject to the scope defined by the claims.

What is claimed is:

1. A method for forming a semiconductor structure, comprising:
providing a base;
forming a first electrode layer on the base; and
forming a capacitor dielectric layer with a stacked structure on the first electrode layer and a second electrode layer on the capacitor dielectric layer, the capacitor dielectric layer comprising:
a bottom high-k dielectric layer,
a leakage-proof dielectric layer, and
a top high-k dielectric layer that are sequentially stacked from a bottom to a top,
wherein the bottom high-k dielectric layer and the top high-k dielectric layer have a preset total deposition thickness, and
wherein a proportion of a deposition thickness of the bottom high-k dielectric layer to the preset total deposition thickness is greater than a proportion of a deposition thickness of the top high-k dielectric layer to the preset total deposition thickness.

2. The method for forming a semiconductor structure according to claim 1, wherein:
after the first electrode layer is formed on the base and before the capacitor dielectric layer with a stacked structure is formed on the first electrode layer and a second electrode layer on the capacitor dielectric layer is formed, the forming method further comprises:
forming a capacitor dielectric film covering the stacked structure of the first electrode layer, the capacitor dielectric film comprising a bottom high-k dielectric film, a leakage-proof dielectric film, and a top high-k dielectric film that are sequentially stacked from a bottom to a top,
wherein the bottom high-k dielectric film and the top high-k dielectric film have a preset total deposition thickness, and
wherein a proportion of a deposition thickness of the bottom high-k dielectric film to the preset total deposition thickness is greater than a proportion of a deposition thickness of the top high-k dielectric film to the preset total deposition thickness;
the step of forming the second electrode layer comprises:
forming an electrode film covering the capacitor dielectric film; and
patterning the electrode film to form a second electrode layer above a part of the first electrode layer; and
the step of forming the capacitor dielectric layer comprises: after the second electrode layer is formed, removing the capacitor dielectric film exposed from the second electrode layer, and retaining, as the capacitor dielectric layer, the capacitor dielectric film remaining between the second electrode layer and the first electrode layer.

3. The method for forming a semiconductor structure according to claim 1, wherein a process for forming the capacitor dielectric layer comprises an atomic layer deposition process or a plasma chemical vapor deposition process.

4. The method for forming a semiconductor structure according to claim 2, wherein the step of removing the capacitor dielectric film exposed from the second electrode layer comprises: etching the capacitor dielectric film exposed from the second electrode layer using an anisotropic dry etching process.

5. The method for forming a semiconductor structure according to claim 1, wherein in the step of forming a capacitor dielectric layer with a stacked structure on the first electrode layer, a proportion of the deposition thickness of the top high-k dielectric layer to the deposition thickness of the bottom high-k dielectric layer is 0.5 to 0.9.

6. The method for forming a semiconductor structure according to claim 1, wherein in the step of forming a capacitor dielectric layer with a stacked structure on the first electrode layer, the deposition thickness of the bottom high-k dielectric layer is 1.5 nanometers to 4 nanometers.

7. The method for forming a semiconductor structure according to claim 1, wherein a front layer metal interconnect structure is formed in the base, a top surface of the front layer metal interconnect structure being exposed from the base, wherein:
before the first electrode layer is formed, the forming method further comprises:
forming an etch stop layer on the base, the etch stop layer covering the front layer metal interconnect structure; and
forming an interlayer dielectric layer on the etch stop layer; and
in the step of forming the first electrode layer, the first electrode layer is formed on the interlayer dielectric layer.

8. The method for forming a semiconductor structure according to claim 1, wherein:
the bottom high-k dielectric layer is made of a material comprising titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate; and
the top high-k dielectric layer is made of a material comprising titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate.

9. The method for forming a semiconductor structure according to claim 1, wherein the leakage-proof dielectric layer is made of a material comprising aluminum oxide, silicon oxide, or silicon nitride.

10. The method for forming a semiconductor structure according to claim 1, wherein the first electrode layer is made of nitrided metal.

11. The method for forming a semiconductor structure according to claim 1, wherein the first electrode layer is made of a material comprising TiN, TaN, or WN.

12. A semiconductor structure, comprising:
a base;
a first electrode layer located on the base;
a capacitor dielectric layer with a stacked structure located on the first electrode layer, the capacitor dielectric layer comprising:
a bottom high-k dielectric layer,
a leakage-proof dielectric layer, and
a top high-k dielectric layer that are sequentially stacked from a bottom to a top,
wherein the bottom high-k dielectric layer and the top high-k dielectric layer have a preset total deposition thickness, and
wherein a proportion of a deposition thickness of the bottom high-k dielectric layer to the preset total deposition thickness is greater than a proportion of a deposition thickness of the top high-k dielectric layer to the preset total deposition thickness; and
a second electrode layer located on the capacitor dielectric layer.

13. The semiconductor structure according to claim 12, wherein a proportion of the deposition thickness of the top high-k dielectric layer to the deposition thickness of the bottom high-k dielectric layer is 0.5 to 0.9.

14. The semiconductor structure according to claim 12, wherein the deposition thickness of the bottom high-k dielectric layer is 1.5 nanometers to 4 nanometers.

15. The semiconductor structure according to claim 12, wherein:
a front layer metal interconnect structure is formed in the base, a top surface of the front layer metal interconnect structure being exposed from the base,
the semiconductor structure further comprises:
an etch stop layer located on the base, where the etch stop layer covers the front layer metal interconnect structure; and
an interlayer dielectric layer located on the etch stop layer,
the first electrode layer being located on the interlayer dielectric layer.

16. The semiconductor structure according to claim 12, wherein:
the bottom high-k dielectric layer is made of a material comprising titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate; and
the top high-k dielectric layer is made of a material comprising titanium oxide, cobalt oxide, nickel oxide, copper oxide, zinc oxide, zirconium oxide, hafnium oxide, tantalum oxide, tungsten oxide, strontium titanate, strontium zirconate, or strontium ruthenate.

17. The semiconductor structure according to claim 12, wherein the leakage-proof dielectric layer is made of a material comprising aluminum oxide, silicon oxide, or silicon nitride.

18. The semiconductor structure according to claim 12, wherein the first electrode layer is made of nitrided metal.

19. The semiconductor structure according to claim 12, wherein the first electrode layer is made of a material comprising TiN, TaN, or WN.
